(19) United States
(12) Patent Application Publication
(10) Pub. No.: US 2005/0191817 A1
(43) Pub. Date: Sep. 1, 2005

(54) Semiconductor device and method of fabricating the same

(76) Inventors: Toshiaki Komukai, Kawasaki-shi (JP); Hideaki Harakawa, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/066,227

(22) Filed: Feb. 25, 2005

(30) Foreign Application Priority Data
Feb. 27, 2004 (JP) 2004-053165

(51) Int. Cl. H01L 21/336; H01L 21/3205

(52) U.S. Cl. 438/305; 438/303; 438/301; 438/595

(57) ABSTRACT

According to an aspect of the invention, there is provided a semiconductor device comprising a semiconductor substrate, a gate electrode formed on the substrate via a gate insulating film and containing silicon, an insulating offset spacer formed on a side surface of the gate electrode and having an upper surface lower than an upper surface of the gate electrode, an insulating sidewall spacer formed on an upper side surface of the gate electrode and on a side surface of the offset spacer by using a material different from the offset spacer, a lightly doped impurity diffusion layer formed in the semiconductor substrate so as to sandwich the gate electrode, a heavily doped impurity diffusion layer formed in the semiconductor substrate in a position deeper than the lightly doped impurity diffusion layer, so as to sandwich the gate electrode and sidewall spacer, and a silicide film formed on the gate electrode.

### CROSS-REFERENCE TO RELATED APPLICATIONS

This application is based upon and claims the benefit of priority from prior Japanese Patent Application No. 2004-053165, filed Feb. 27, 2004, the entire contents of which are incorporated herein by reference.

### BACKGROUND OF THE INVENTION

1. Field of the Invention

The present invention relates to a semiconductor device having an offset spacer on the side surfaces of the gate electrode of a MOSFET, and a method of fabricating the same.

2. Description of the Related Art

The recent advance of micropatterning of semiconductor devices makes it necessary to design MOSFETs by taking account of not only the withstand voltage but also of the short channel effect, the device performance, the density of integration, and the complexity of fabrication processes. An extension structure is used to realize MOS (MIS) transistors in these increasingly micropatterned semiconductor devices. Also, MOS (MIS) transistors used in logic circuits are required to further increase the operating speed. To realize this high-speed operation, a technique of forming a silicide film as a low-resistance material on the gate electrode and on the source and drain regions is important.

To further suppress the short channel effect in the extension structure, there is a technique by which after an offset spacer is formed on the side walls of the gate electrode, a shallow lightly doped impurity diffusion layer is formed (Jpn. Pat. Appln. KOKAI Publication No. 2002-289841).

FIGS. 2A to 2E correspond to FIGS. 7(a) to 7(e) of Jpn. Pat. Appln. KOKAI Publication No. 2002-289841. In a step of forming a metal silicon film 110 shown in FIG. 2E, before the metal film is deposited, wet etching must be performed to remove a natural oxide film and the like and to completely expose a gate electrode 113a and heavily doped source/drain regions 107. By this wet etching, an offset spacer 114a and side walls 109 partially recede. Therefore, the metal silicon film 110 is formed with the upper side surfaces of the gate electrode 113a exposed. Consequently, the metal is excessively supplied to the side walls of the gate electrode 113a to cause abnormal growth of the metal silicide film 110, thereby acceleratedly decreasing the resistance of a thin line portion having a gate width.

Note that if a material other than a silicon oxide film is used as the offset spacer, hot carriers are generated, so the threshold voltage rises. Accordingly, it is unpreferable to use a material other than a silicon oxide film as the offset spacer.

As described above, there is the problem that when wet etching is performed, the offset spacer and side walls recede to expose the upper side surfaces of the gate electrode, and this causes the abnormal growth of the metal silicide film.

### BRIEF SUMMARY OF THE INVENTION

According to an aspect of the invention, there is provided a semiconductor device comprising: a semiconductor substrate; a gate electrode formed on the semiconductor substrate via a gate insulating film and containing silicon; an insulating offset spacer formed on a side surface of the gate electrode and having an upper surface lower than an upper surface of the gate electrode; an insulating sidewall spacer formed on an upper side surface of the gate electrode and on a side surface of the offset spacer by using a material different from the offset spacer; a lightly doped impurity diffusion layer formed in the semiconductor substrate so as to sandwich the gate electrode; a heavily doped impurity diffusion layer formed in the semiconductor substrate in a position deeper than the lightly doped impurity diffusion layer, so as to sandwich the gate electrode and sidewall spacer; and a silicide film formed on the gate electrode.

According to another aspect of the invention, there is provided a semiconductor device fabrication method comprising: forming a gate electrode containing silicon on a semiconductor substrate via a gate insulating film; forming an offset spacer on a side surface of the gate electrode; forming a lightly doped impurity diffusion layer on a surface of the semiconductor substrate by using the offset spacer and gate electrode as masks; causing an upper surface of the offset spacer to recede; forming a sidewall spacer on the side surface of the gate electrode and on a side surface of the offset spacer; forming, on the surface of the semiconductor substrate, a heavily doped impurity diffusion layer having an impurity concentration higher than that of the lightly doped impurity diffusion layer by using the sidewall spacer, offset spacer, and gate electrode as masks; supplying, onto the semiconductor substrate, a solution which selectively removes the offset spacer with respect to the sidewall spacer; depositing a metal layer on the semiconductor substrate; and allowing the gate electrode and metal layer to react with each other, thereby forming a silicide film.

### BRIEF DESCRIPTION OF THE SEVERAL VIEWS OF THE DRAWING

FIGS. 1A to 1K are sectional views showing the steps of fabricating a semiconductor device according to an embodiment of the present invention; and

FIGS. 2A to 2E are sectional views showing the steps of fabricating a semiconductor device according to the prior art.

### DETAILED DESCRIPTION OF THE INVENTION

An embodiment of the present invention will be described below with reference to the accompanying drawing.

In this embodiment, in the technique which forms a metal silicide film, which is a low resistance material, on the gate electrode and on the source/drain regions, an even metal silicide film is formed not only on the source/drain regions but also on particularly the gate electrode which is a thin line.

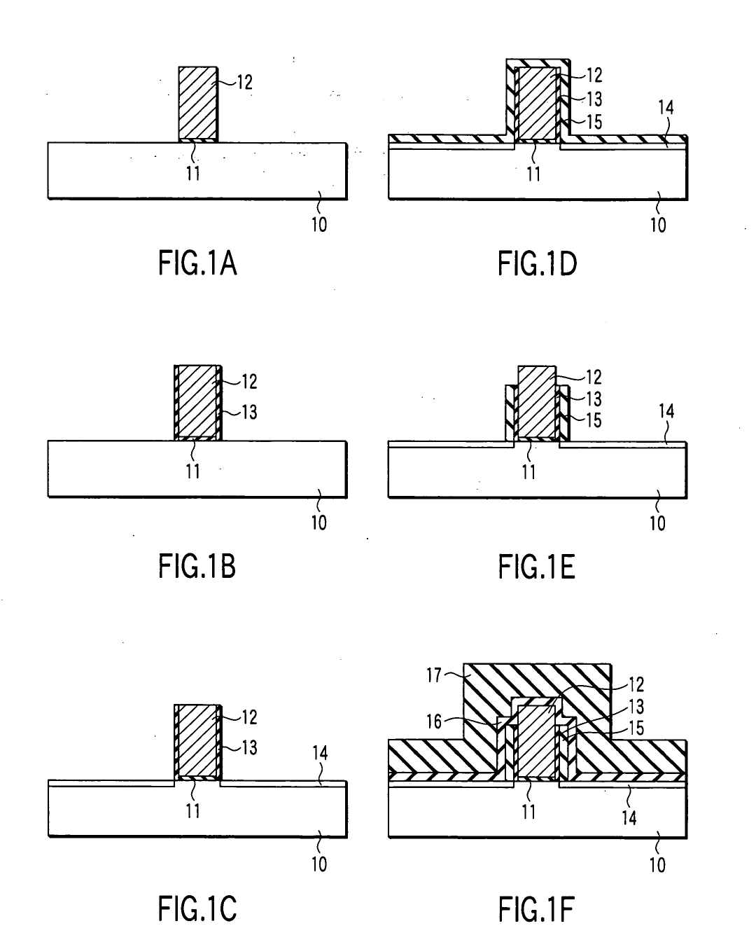

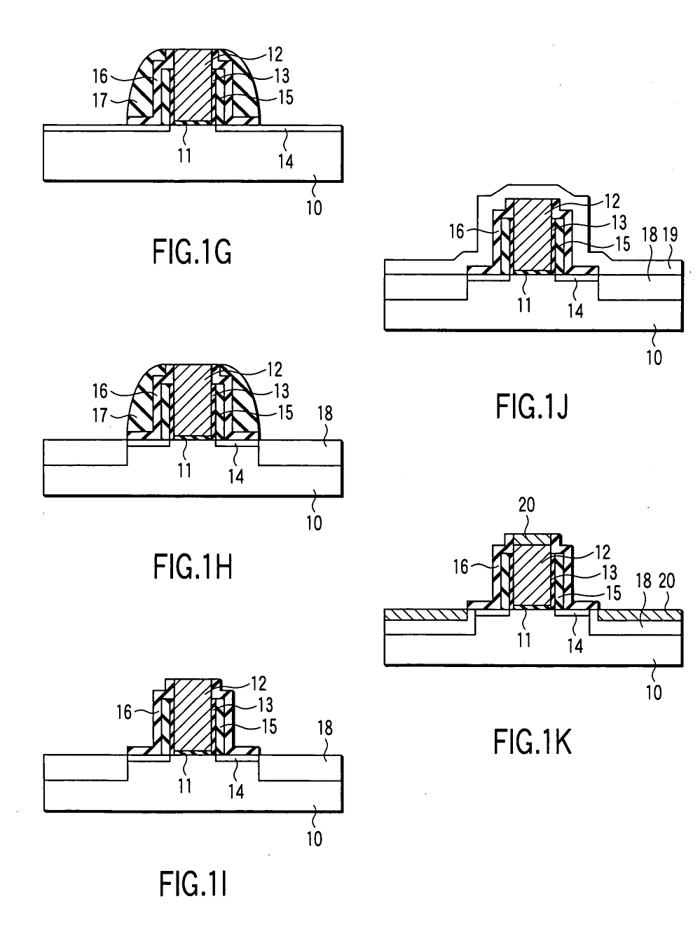

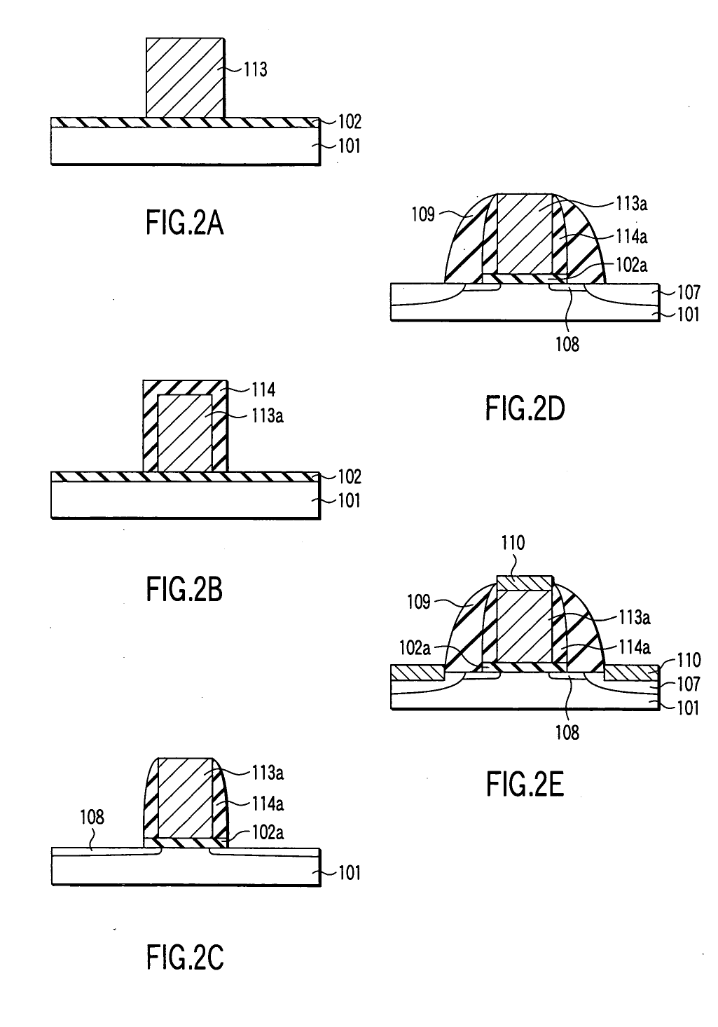

As shown in FIG. 1A, a gate insulating film 11 and a gate electrode material made of polysilicon are deposited on a silicon substrate (semiconductor substrate) 10, and a gate electrode 12 and the gate insulating film 11 are patterned. As shown in FIG. 1B, a silicon oxide film about 10 nm thick is deposited on the entire surface of the silicon substrate 10, and anisotropic etching is performed to form an offset spacer 13 made of the silicon oxide film on the side walls of the gate electrode 12. As shown in FIG. 1C, the gate electrode 12 and offset spacer 13 thus formed are used as masks to dope an impurity, thereby forming, on the surface of the silicon substrate 10, a shallow lightly doped impurity diffusion layer 14 which is adjacent to and sandwiches the gate electrode 12.

Then, as shown in FIG. 1D, a silicon oxide film 15 is deposited on the entire surface of the silicon substrate 10. As shown in FIG. 1E, anisotropic etching is performed under conditions by which a silicon oxide is selectively etched, thereby removing the silicon oxide film 15 on the gate electrode 12 and on the lightly doped impurity diffusion layer 14. By this anisotropic etching, the upper surfaces of the offset spacer 13 and silicon oxide film 15 recede from the upper surface of the gate electrode 12, and a step is formed.

As shown in FIG. 1F, a silicon nitride film 16 and silicon oxide film 17 are sequentially deposited on the entire surface. As shown in FIG. 1G, anisotropic etching is performed to remove the silicon oxide film 17 and silicon nitride film 16 on the gate electrode 12 and on the lightly doped impurity diffusion layer 14. The silicon nitride film (sidewall spacer) 16 has a sectional shape obtained by connecting two L-shapes. In this manner, the sidewall spacer 16 is formed on the side surfaces of the gate electrode 12 and on the side surfaces of the offset spacer 13 (silicon oxide film 15).

As shown in FIG. 1H, the gate electrode 12, offset spacer 13, sidewall spacer 16, and silicon oxide film 17 are used as masks to dope an impurity into the silicon substrate 10, thereby forming, on the surface of the silicon substrate 10, a heavily doped impurity diffusion layer 18 (having an impurity concentration higher than that of the lightly doped impurity diffusion layer 14) which is separated from the end portion of the gate electrode 12 and sandwiches the gate electrode 12 and silicon nitride film 16.

Then, as shown in FIG. 1I, a natural oxide film on the surfaces of the gate electrode 12 and heavily doped impurity diffusion layer 18 is removed by wet etching using hydrofluoric acid. In this wet etching, a solution which selectively removes the offset spacer 13 with respect to the sidewall spacer 16 is supplied onto the silicon substrate 10. By this wet etching, the silicon oxide film 17 is removed, but the offset spacer 13 and silicon oxide film 15 are not etched because they are covered with the silicon nitride film 16.

As shown in FIG. 1J, a metal film 19 made of nickel or the like is deposited on the entire surface of the silicon substrate 10. As shown in FIG. 1K, the exposed surface portions of the gate electrode 12 and heavily doped impurity diffusion layer 18 are annealed to a temperature at which these portions react with the metal layer 19, thereby forming a metal silicide film 20 in self-alignment. Finally, the unreacted metal film is selectively removed.

In this embodiment as described above, the upper side surfaces of the gate electrode 12 and the side surfaces of the silicon oxide film 15 are covered with the silicon nitride film 16, so the silicon oxide films (the offset spacer 13 and silicon oxide film 15) do not recede during wet etching. Since this prevents excess supply of the metal, an even metal silicide film 20 can be formed.

This embodiment provides a semiconductor device capable of suppressing the abnormal growth of a metal silicide film on the upper side surfaces of the gate electrode, and a method of fabricating the same.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
a gate electrode formed on the semiconductor substrate via a gate insulating film and containing silicon;
an insulating offset spacer formed on a side surface of the gate electrode and having an upper surface lower than an upper surface of the gate electrode;
an insulating sidewall spacer formed on an upper side surface of the gate electrode and on a side surface of the offset spacer by using a material different from the offset spacer;
a lightly doped impurity diffusion layer formed in the semiconductor substrate so as to sandwich the gate electrode;
a heavily doped impurity diffusion layer formed in the semiconductor substrate in a position deeper than the lightly doped impurity diffusion layer, so as to sandwich the gate electrode and sidewall spacer; and
a silicide film formed on the gate electrode.

2. The device according to claim 1, wherein the sidewall spacer is formed on the lightly doped impurity diffusion layer.

3. The device according to claim 1, wherein the sidewall spacer is made of a silicon nitride film.

4. A semiconductor device fabrication method comprising:
forming a gate electrode containing silicon on a semiconductor substrate via a gate insulating film;
forming an offset spacer on a side surface of the gate electrode;
forming a lightly doped impurity diffusion layer on a surface of the semiconductor substrate by using the offset spacer and gate electrode as masks;
causing an upper surface of the offset spacer to recede;
forming a sidewall spacer on the side surface of the gate electrode and on a side surface of the offset spacer;
forming, on the surface of the semiconductor substrate, a heavily doped impurity diffusion layer having an impurity concentration higher than that of the lightly doped impurity diffusion layer by using the sidewall spacer, offset spacer, and gate electrode as masks;
supplying, onto the semiconductor substrate, a solution which selectively removes the offset spacer with respect to the sidewall spacer;
depositing a metal layer on the semiconductor substrate; and
allowing the gate electrode and metal layer to react with each other, thereby forming a silicide film.

5. The method according to claim 4, wherein
after the lightly doped impurity diffusion layer is formed, an insulating film formed by using the same material as the offset spacer is deposited on the semiconductor substrate, and anisotropic etching is performed to cause the upper surface of the offset spacer to recede, and remove the insulating film on the lightly doped impurity diffusion layer and gate electrode.

6. The device according to claim 1, wherein the offset spacer comprises a silicon oxide film.

7. The device according to claim 1, wherein a silicide film is formed on the heavily doped impurity diffusion layer.

8. The method according to claim 4, wherein the offset spacer comprises a silicon oxide film.

9. The method according to claim 4, wherein the sidewall spacer comprises a silicon nitride film.

10. The method according to claim 4, wherein a silicide film is formed on the heavily doped impurity diffusion layer.

11. The method according to claim 5, wherein the offset spacer and insulating film are made of silicon oxide films.

12. A semiconductor device comprising:
a semiconductor substrate;
a gate electrode formed on the semiconductor substrate via a gate insulating film and containing silicon;
an insulating offset spacer formed on a side surface of the gate electrode and having an upper surface lower than an upper surface of the gate electrode;
an insulating sidewall spacer formed on an upper side surface of the gate electrode and on a side surface of the offset spacer by using a material different from the offset spacer;
an insulating film formed between the sidewall spacer and the offset spacer by using the same material as the offset spacer, the insulating film having an upper surface lower than an upper surface of the gate electrode;
a lightly doped impurity diffusion layer formed in the semiconductor substrate so as to sandwich the gate electrode;
a heavily doped impurity diffusion layer formed in the semiconductor substrate in a position deeper than the lightly doped impurity diffusion layer, so as to sandwich the gate electrode and sidewall spacer; and
a silicide film formed on the gate electrode.

13. The device according to claim 12, wherein the offset spacer and insulating films are made of silicon oxide films.
